(19) United States
(12) Patent Application Publication
(10) Pub. No.: US 2010/0126567 A1
(43) Pub. Date: May 27, 2010

(54) SURFACE PLASMON ENERGY CONVERSION DEVICE

(75) Inventor: Lawrence A. Kaufman, Waltham, MA (US)

Correspondence Address: Milstein Zhang & Wu LLC, 49 Lexington Street, Suite 6, Newton, MA, 02465-1062, US

(73) Assignee: Lightwave Power, Inc., Cambridge, MA (US)

(21) Appl. No.: 12/623,157

(22) Filed: Nov. 20, 2009

Related U.S. Application Data
(60) Provisional application No. 61/116,743, filed on Nov. 21, 2008.

(51) Int. Cl. H01L 31/0232; G02B 26/00

(52) U.S. Cl. 136/252; 359/238

(57) ABSTRACT

The invention relates to a surface plasmon energy converter device which includes a first layer having a first layer dielectric constant. A plurality of nanofeatures is disposed in or on the first layer. A second layer has a second layer dielectric constant which differs from the first layer dielectric constant. The surface plasmon energy converter device is configured to respond to an incident electromagnetic radiation having a first wavelength by radiating away from the surface plasmon wavelength converter device an electromagnetic radiation having a second wavelength different from the first wavelength. The invention also relates to a surface plasmon energy converter device which has a first layer having a first plurality of nanofeatures disposed on a first layer surface, a second layer having a second plurality of nanofeatures disposed on a second layer surface. The invention also relates to a surface plasmon energy converter device for generating electricity.

### CROSS-REFERENCE TO RELATED APPLICATIONS

This application claims priority to and the benefit of co-pending U.S. provisional patent application Ser. No. 61/116,743, Two-Dimensional Photonic Crystal Structures, filed Nov. 21, 2008, which application is incorporated herein by reference in its entirety.

### FIELD OF THE INVENTION

The invention relates to surface plasmon energy conversion devices in general and particularly to a surface plasmon energy conversion device that employs wavelength conversion.

### BACKGROUND OF THE INVENTION

FIG. 1 shows an illustration of a prior art solar cell 100 made from amorphous silicon (α-Si) on glass. The solar cell absorbing region comprises three layers: p-type α-Si 101, intrinsic α-Si 103, and n-type α-Si 105 formed on glass 119. These layers differ in doping, and may also differ in material composition. A back metal contact 107 serves also as a back reflector. Rays 111 incident on the front surface propagate toward the back contact 107 and those photons reaching the back are reflected toward the front surface and a fraction will propagate out of the solar cell (ray 113). The thickness of the absorbing region 117 governs the amount of light that will be absorbed in accordance with Beer's Law. Reflection from the back metal increases the effective optical thickness (i.e. the total distance the light travels within the absorbing material) by a factor dependent on the reflectance, but in all cases if the reflection is specular this multiplicative factor is less than 2. The use of light scattering at the back surface can increase the effective path length multiplier to more than 2 by scattering some light into trajectories that are trapped by total internal reflection, as shown by ray 115. Not all of the light is scattered into angles that are trapped. Prior art solar cells also include tandem structures in which the absorbing region comprises a plurality of materials wherein each material forms a complete solar cell.

What is needed, therefore, are structures that can more efficiently make use of incident electromagnetic radiation, such as for example, to increase the conversion efficiency of a solar cell.

### SUMMARY OF THE INVENTION

In one aspect, the invention relates to a surface plasmon energy converter device which includes a first layer having a first layer dielectric constant, a first layer first surface and a first layer second surface. A plurality of nanofeatures is disposed in or on the first layer. A second layer has a second layer dielectric constant and a second layer first surface and a second layer second surface, the second layer second surface is disposed adjacent to and optically to the first layer second surface. The second layer dielectric constant differs from the first layer dielectric constant. The surface plasmon energy converter device is configured to respond to an incident electromagnetic radiation having a first wavelength by radiating away from the surface plasmon wavelength converter device an electromagnetic radiation having a second wavelength different from the first wavelength.

In one embodiment, the first layer has a first plurality of nanofeatures which is configured to absorb the first wavelength.

In another embodiment, the second layer is configured to radiate an electromagnetic radiation at the second wavelength.

In yet another embodiment, the surface plasmon energy converter device further includes an interfacial layer disposed between the first layer second surface and the second layer second surface.

In yet another embodiment, the interfacial layer has a thickness substantially equal to or less than 15 nm.

In yet another embodiment, the first layer includes a selected one of oxide and nitride dielectric.

In yet another embodiment, the dielectric is selected from the group consisting of oxide, nitride dielectric, silicon dioxide, titanium dioxide, zinc oxide, tin oxide, indium oxide, silicon nitride, aluminum nitride, boron nitride, and titanium nitride.

In yet another embodiment, the nanofeatures include a selected one of silver, gold, copper, aluminum, metal alloy, and mercury.

In yet another embodiment, the nanofeatures are sized in a range of approximately 50 nm to 200 nm.

In yet another embodiment, an integrated solar cell, includes a surface plasmon energy converter device having at least one solar cell layer optically coupled thereto, and a first positive electrical terminal and a second negative terminal. The first positive electrical terminal and the second negative terminal are configured to provide an electrical current and an electrical voltage as output signals.

In yet another embodiment, the integrated solar cell, further includes at least one additional surface plasmon energy converter device. The additional second surface plasmon wavelength converter device is optically coupled to the solar cell.

In another aspect, the invention relates to a surface plasmon energy converter device which includes a first layer having a first plurality of nanofeatures disposed on a first layer first surface, and a first layer second surface. A second layer has a second plurality of nanofeatures disposed on a second layer first surface, and a second layer second surface disposed adjacent to and optically coupled to the first layer second surface. The surface plasmon energy converter device is configured to respond to an incident electromagnetic radiation having a first wavelength by radiating away from the surface plasmon wavelength converter device an electromagnetic radiation having a second wavelength different from the first wavelength.

In one embodiment, the first layer has a first plurality of nanofeatures configured to absorb the electromagnetic radiation at the first wavelength.

In another embodiment, the second layer having a second plurality of nanofeatures is configured to radiate the electromagnetic radiation at the second wavelength.

In yet another embodiment, the first plurality of nanofeatures includes a metal.

In yet another embodiment, the metal includes silver.

In yet another embodiment, the first plurality of nanofeatures includes cylinders having a diameter of approximately 50 to 180 nm, a thickness of approximately 30 to 50 nm and a pitch of about two to six times the cylinder diameter.

In yet another embodiment, the first plurality of nanofeatures is arranged in a square lattice.

In yet another embodiment, the first plurality of nanofeatures includes shapes selected from the group consisting of a triangle and a cylinder.

In yet another embodiment, the first layer includes a dielectric material.

In yet another embodiment, the first layer includes a selected one of oxide and nitride dielectric.

In yet another embodiment, the dielectric is selected from the group consisting of oxide, nitride dielectric, silicon dioxide, titanium dioxide, zinc oxide, tin oxide, indium oxide, silicon nitride, aluminum nitride, boron nitride, and titanium nitride.

In yet another embodiment, the integrated solar cell includes a surface plasmon energy converter device having at least one solar cell layer optically coupled thereto, and a first positive electrical terminal and a second negative terminal. The first positive electrical terminal and the second negative terminal are configured to provide an electrical current and an electrical voltage as output signals.

In yet another embodiment, the integrated solar cell further includes at least one additional surface plasmon energy converter device. The additional second surface plasmon wavelength converter device optically is coupled to the solar cell.

In yet another aspect, the invention relates to a surface plasmon energy converter device for generating electricity which includes a first layer having a first layer dielectric constant, a first layer first surface and a first layer second surface. A second layer has a second layer dielectric constant and a plurality of nanofeatures having an asymmetric shape disposed on or in the second layer, a second layer first surface and a second layer second surface. The second layer second surface is disposed adjacent to and optically to the first layer second surface. The surface plasmon energy converter device also includes a first electrical terminal and a second electrical terminal. The surface plasmon energy converter device is configured to respond to an incident electromagnetic radiation having a first wavelength by causing an electrical current to flow between the first electrical terminal and the second electrical terminal.

In one embodiment, the asymmetric shape includes a triangular shape.

In another embodiment, the first layer includes transparent conductive layer.

In yet another embodiment, the transparent conductive layer includes an indium tin oxide.

In yet another embodiment, the nanofeatures are disposed in a lattice pattern.

In yet another embodiment, the incident electromagnetic radiation includes photons of light.

In yet another embodiment, the surface plasmon energy converter device is configured as a rectenna, a rectifying antenna which converts a received electromagnetic radiation into an electrical current.

In yet another embodiment, the incident electromagnetic radiation includes radio waves.

In yet another embodiment, the surface plasmon energy converter device further includes an additional layer disposed between the first layer and the second layer, the additional layer including nanowires.

In yet another embodiment, the surface plasmon energy converter device further includes an additional layer disposed between the first layer and the second layer, the additional layer including graphene.

In yet another embodiment, the first layer includes a selected one of graphene and nanowires.

In yet another embodiment, the first layer comprises a material having a first resistance in a plane of the first layer and a second resistance perpendicular to the plane of the first layer and the first resistance is less than the second resistance.

The foregoing and other objects, aspects, features, and advantages of the invention will become more apparent from the following description and from the claims.

### BRIEF DESCRIPTION OF THE DRAWINGS

For a further understanding of these and objects of the invention, reference will be made to the following Detailed Description, which is to be read in connection with the accompanying drawings, where:

FIG. 1 shows an illustration of a prior art solar cell.

FIG. 2A shows an illustration of one embodiment of a surface plasmon energy conversion device having an interfacial layer according to the invention.

FIG. 2B shows an illustration of one embodiment of a surface plasmon energy conversion device without an interfacial layer according to the invention.

FIG. 3 shows an illustration of another exemplary embodiment of an integrated solar cell device.

FIG. 4 shows a plan view of one exemplary nanoparticle layer.

FIG. 5 shows a cross section view of the nanoparticle of FIG. 4.

FIG. 6 shows an illustration of an integrated solar cell having a plasmonic layer overlaying a solar cell.

FIG. 7 shows an illustration of an exemplary plasmonic structure where a plasmonic nanoparticle layer is disposed adjacent to an AR coating.

FIG. 8 shows an illustration of another exemplary plasmonic structure where a plasmonic nanoparticle layer is disposed between an absorbing layer and a back contact layer.

FIG. 9 shows a symbolic representation of one exemplary embodiment of a stacked layered structure.

FIG. 10 shows a symbolic diagram which illustrates a principle of operation of an energy converting plasmonic device.

FIG. 11 shows an illustration of one exemplary embodiment of an energy converting plasmonic device according to FIG. 10.

FIG. 12 shows an embodiment of an energy converting plasmonic device using nanowires.

FIG. 13 shows embodiment of an energy converting plasmonic device using a graphene plane.

FIG. 14 shows an embodiment of an energy converting plasmonic device using a plane of conductive material.

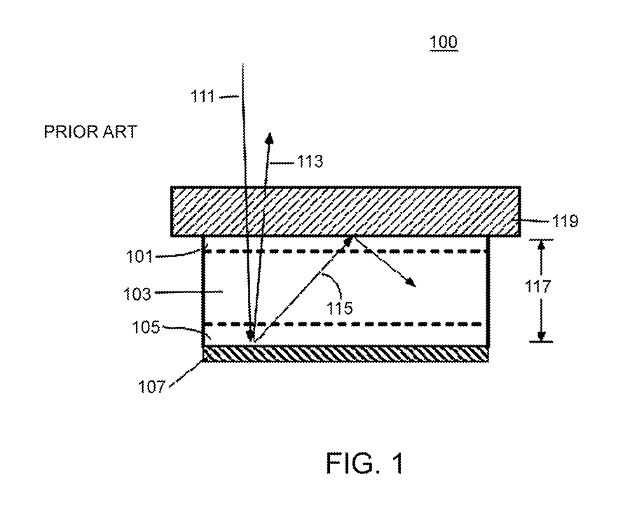

The drawings are not necessarily to scale, emphasis instead generally being placed upon illustrating the principles of the invention. In the drawings, like numerals are used to indicate like parts throughout the various views.

### DETAILED DESCRIPTION

### Definitions

“Nanofeatures” are defined as (i) one or more types made of metallic nanoscale structures or particles typically embedded in or on a dielectric (including a solid dielectric, liquid dielectric, air, dielectric gas, or vacuum), insulator, semiconductor, polymer, or other material having a different dielectric coefficient than the metallic nanoscale structures or particles such as an oxide film, and (ii) one or more type of non-metallic nanoscale particles or structures made of a dielectric material (including a solid dielectric, liquid dielectric, air, dielectric gas, or vacuum), semiconductor, insulator, polymer or other material typically embedded in or on a metallic material having a different dielectric coefficient than the non-metallic nanoscale particles materials such a metal film.

“Nanofeature layer” is defined as (i) layers of nanofeatures, and (ii) layers of metals or other conductive media that have an array of nanoscale voids, depressions, protrusions, or other nanoscale patterns.

“Nanofeature array” is defined as a nanofeature layer having a repeated pattern of nanoscale features. A nanofeature array can also include any suitable combination of features, such as for example, a metallic layer such as a metallic film having two or more types of dielectric nanofeatures. A nanofeature array can also include a dielectric layer with a plurality of patterns of metallic nanofeatures, or other nanoscale features in any suitable combination. A nanofeature array typically has one or more periodic patterns of nanofeatures.

### Surface Plasmon Energy Conversion Devices:

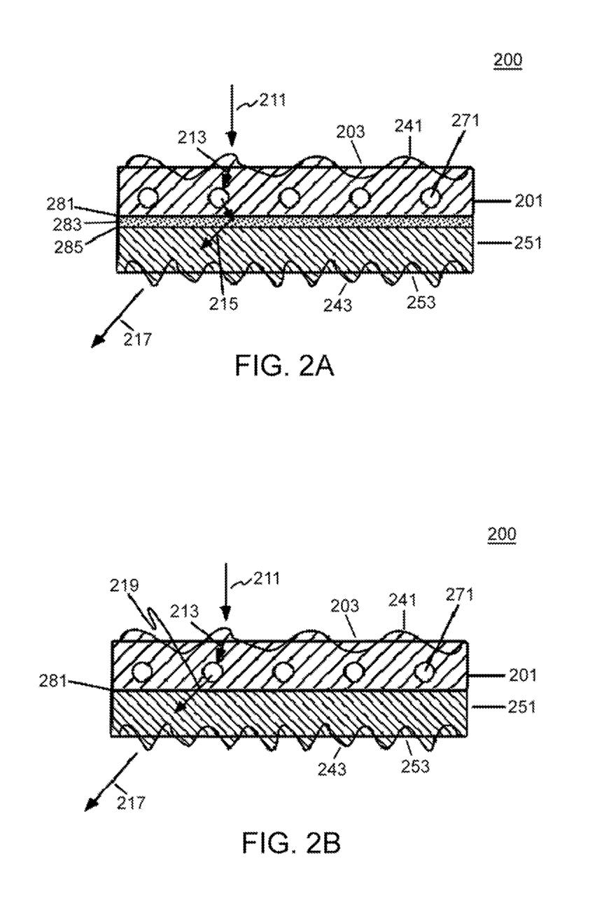

FIG. 2A shows an illustration of one embodiment of a surface plasmon energy conversion device 200 according to the invention. A second surface of a nanoparticle layer 201 is disposed adjacent to and in physical contact with a thin interfacial layer 283 at interface 281. Interfacial layer 283 is also in contact with a second surface of second layer 251 at an interface 285. The interfacial layer 283 is typically less than 15 nm in thickness. FIG. 2B shows an illustration of another embodiment of a surface plasmon energy conversion device 200 where the thickness of interfacial layer 283 is essentially zero, and interface 281 and interface 285 become a single interface 281.

Referring now to both FIG. 2A and FIG. 2B, substantially opposite to its second surface, nanoparticle layer 201 has a first surface 203. Similarly, substantially opposite to its second surface, the second layer 251 has a first surface 253. Nanoparticle layer 201 and the second layer 251 are made of different materials and have different dielectric constants and different surface plasmon resonances. Nanoparticle layer 201 includes a plurality of nanoparticles 271. Nanoparticle Layer 201 and second layer 251 can be made from, for example, oxide or nitride dielectrics such as silicon dioxide, titanium dioxide, zinc oxide, tin oxide, indium oxide, silicon nitride, aluminum nitride, boron nitride, titanium nitride or from any other suitable metal oxides. Nanoparticles 271 can be made from any suitable electrically conductive material such as silver, gold, copper, aluminum or a metal alloy and combinations and alloys thereof. The nanoparticles can alternatively be made of a fluid, such as for example, mercury. Nanoparticles 271 preferably have a disk shape, such as a relatively thin flat cylinder (i.e., having a larger diameter than thickness), however any other suitable shape such as a spherical or an ellipsoidal shape can be used. Nanoparticles 271 are typically sized in a range of about 50 nm to 200 nm. The size of nanoparticle particles 271 as well as the complex index of refraction of the materials can be selected for a particular wavelength. Methods such as finite difference time domain modeling can be used to determine an optimum size and shape as well as material characteristics (e.g. complex index of refraction). Alternatively, layers 201 and 251 can be made from any suitable conductor such as silver, gold, aluminum, copper or a metallic alloy and combinations and alloys thereof. Nanoparticles 271 can comprise either a dielectric or metal having a conductivity different from material 201. Nanoparticles 271 can include: holes, voids, a vacuum, solids, fluids, or gases and can have any other suitable shape such as those described hereinbelow.

Turning to the embodiment of FIG. 2A, electromagnetic radiation 211 incident at surface 203 of nanoparticle layer 201 causes surface plasmon waves 241 to propagate along the surface 203. Nanoparticles 271 couple surface plasmon waves 241 to surface plasmons or other states (not shown) in interfacial region 283 via energy transfer mechanisms represented by ray 213 and ray 215 which can include non-radiative dipole-dipole interactions. At least a portion of the energy in the interfacial states or in the surface plasmons within interfacial region 283 is coupled to surface plasmon waves 243 on a surface 253 of second layer 251, such as by the non-radiative process represented by ray 215. Turning now to FIG. 2B, where interfacial region 283 is absent, a non-radiative process represented by ray 219 can couple energy from the nanoparticle 271 to surface wave 243. Energy absorbed from coupled surface plasmon waves 241 is thus transferred to a surface plasmon wave 243 on surface 253 and then emitted as electromagnetic radiation 217.

In both of the embodiments of FIG. 2A and FIG. 2B, the resonant frequencies of the two surface plasmon waves 241 and surface plasmon waves 243 are different because layer 201 and second layer 251 have different surface plasmon resonances. Since the resonant frequencies of the two waves are different, the exemplary surface plasmon energy conversion devices of FIG. 2A and FIG. 2B not only change the propagation direction, but also shift the wavelength of incident electromagnetic radiation 211. Therefore the electromagnetic radiation 217 emitted from the surface of material 243 has a different wavelength than the electromagnetic radiation 211 incident at surface of nanoparticle layer 201. Surface plasmon energy conversion devices 200 as described hereinabove are believed to function by providing a non-linear mixing of electromagnetic radiation.

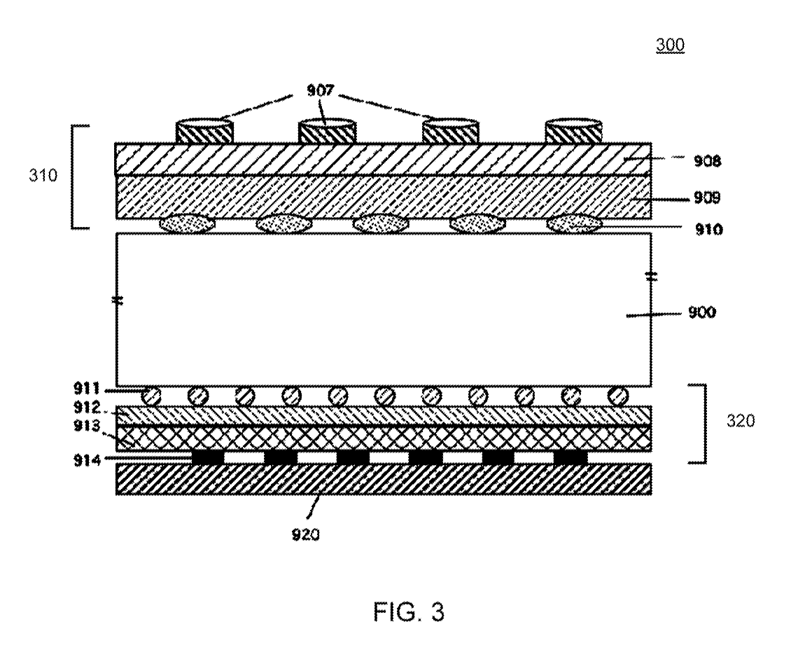

FIG. 3 shows an illustration of another exemplary embodiment of an integrated solar cell device 300. In the embodiment of FIG. 3, surface plasmon energy conversion layers are disposed adjacent to both sides of a solar cell or photovoltaic absorbing layer (e.g. adjacent to the front and back sides of the solar cell absorbing layer). A surface plasmon energy conversion device 310 is shown as disposed adjacent to a first surface of a solar cell 900. Surface plasmon energy conversion device 310 includes two integrated layer structures. A first layer of surface plasmon energy conversion device 310 includes a dielectric or metal layer 908 that has arrays of nanostructures 907 on a first surface. A second layer of surface plasmon energy conversion device 310 includes a dielectric or metal layer 909 having an array of nanostructures 910 on a first surface. The second surface of layer 908 of the first layer is disposed adjacent to the second surface of layer 909 of the second layer.

The two layers of surface plasmon energy conversion device 310 are now described in more detail. Front dielectric or metal layer 908 includes arrays of nanostructures 907 on the outside surface (a surface designed to accept an incident electromagnetic radiation incident on integrated solar cell 300) and is designed to absorb certain wavelengths of light by the creation of surface plasmons as described hereinabove (not shown in FIG. 3). Nanostructures 907 can be made of metals or dielectrics and the shape of the structures can be selected such that incident light interacts with the front surface by excitation of plasmons, which excitation is believed to be attained for wavelengths in which momentum is substantially conserved. The nanostructures 907 are typically smaller than a wavelength of the light desired to be absorbed and can be arranged in a lattice, such as, for example, a square lattice. Alternatively nanostructures 907 can be disposed in random or pseudo random patterns on layer 908. The dimensions and properties of structures 907 and 908, such as size, shape, geometry, and type of materials are chosen to select the desired range of wavelength to be absorbed.

Dielectric or metal layer 909 includes an array of nanostructures 910 on the first surface of layer 909 and is designed to emit the desired modified wavelengths of light. The nanostructures 910 can be made of metals or dielectrics and the shape of the structures is designed so that conservation of momentum insures that incident light is emitted from the back surface by conversion of plasmon energy into light energy. Nanostructures 910 are typically smaller than the desired wavelength of the light to be emitted and nanostructures 910 can be arranged in any suitable lattice or periodic structure, such as for example, in a square lattice, or in a substantially random pattern. The parameters of nanostructures 910 including the size, shape, materials and geometry, are chosen to select a range of wavelengths of light that will be emitted by the structure into the solar cell absorbing layer 900.

### Example

Nanostructures 907 can be made from cylinders of metallic silver with a diameter of 50-180 nm, a thickness of 30-50 nm and a pitch of two to six times the cylinder diameter, with the cylinders, for example, arranged on a square lattice, such that light in the wavelength range 700-1100 nm can induce surface plasmons in the structure. Layer 908 can be made of any suitable dielectric. In some embodiments, layer 908 can be alternatively made of a thin optically transparent metal layer.

Nanoparticles 910 can be made of metallic silver that can be cylinders or other shapes such as triangles, with a diameter of 50-180 nm, a thickness of 30-50 nm and a pitch of two to six times the cylinder diameter, with the cylinders arranged on a square lattice. The parameters of layer 909 and nanoparticles 910 are chosen such that light is emitted at frequencies shifted from and different from the incident light wavelengths. Such wavelength shifting can be achieved by choosing different parameters for nanoparticles 907 and layer 908 as compared to layer 909 and nanoparticles 910. For example, layer 909 and nanoparticles 910 can be made of gold and because the conductivity is different from another type of metal used for nanoparticles 907 and layer 908, the emitted wavelengths will differ.

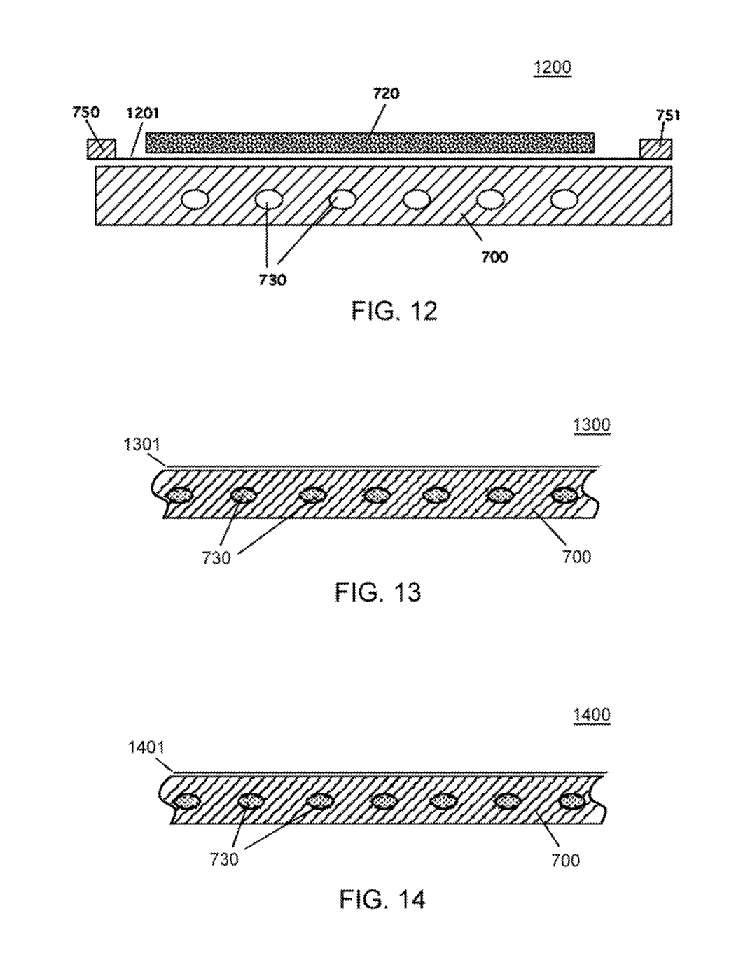

Additional surface plasmon energy conversion devices can be stacked adjacent to a surface plasmon energy conversion device 310 (not shown in FIG. 3) or placed adjacent to an opposite side of a solar cell or photovoltaic layer, e.g. adjacent to a back electrical contact 920 of integrated solar cell 300. For example, a surface plasmon energy conversion device 320 is shown disposed adjacent to the second surface of a solar cell 900 in FIG. 3. Surface plasmon energy conversion device 320 includes nanoparticles 911 disposed on a dielectric or metal layer 912 adjacent to another dielectric or metal layer 913 having nanoparticles 914. The material considerations and physical dimensions of surface plasmon energy conversion device 320 can be selected as described hereinabove with respect to surface plasmon energy conversion device 310. An additional consideration is that light should be reflected from the surface of surface plasmon energy conversion device 320 near electrical contact 920 and pass twice through the nanostructures to pass electromagnetic radiation of a modified wavelength that can be more efficiently absorbed by solar cell 900. It can now be seen that such nanoparticle layers can be disposed on any surface of a solar cell or photovoltaic layer, e.g. in front of or behind the solar cell absorbing layer, or as has been shown in the embodiment of FIG. 12, nanoparticle layer or layers can be provided at both surfaces of a solar cell layer.

### Integrated Solar Cell Component Structures:

FIG. 4 shows a plan view of one exemplary nanoparticle layer formed in a metal sheet 360 having, for example, a thickness in the range of 10 to 200 nm. Surface plasmons (not shown) traveling at the surface 361 of the metal sheet 360 have resonant frequencies that depend in the spacing 371 of the nanoparticles, vias, or depressions 370. The surface plasmon resonant frequencies can be affected by the presence of the nanoscale features. For a periodic structure such as periodic array of apertures, this resonant condition can be described as:

$$λ = {a}_{0} \sqrt{\frac{{ɛ}_{1} {ɛ}_{2}}{{ɛ}_{1} + {ɛ}_{2}}} \qquad ( 1 )$$

where λ is the wavelength of the incident electromagnetic radiation; a₀ is the lattice constant; ∈₁ and ∈₂ are real portions of the respective dielectric constants for the metallic substrate and the surrounding medium in which the incident radiation passes prior to irradiating the metal film. For a non-periodic structure, the above equation can be modified to describe the resonant condition for a non-periodic structure. For example, where a configuration comprises a single aperture at the center of a single annular groove, the resonant condition may be described as:

$$λ = ρ \sqrt{\frac{{ɛ}_{1} {ɛ}_{2}}{{ɛ}_{1} + {ɛ}_{2}}} \qquad ( 2 )$$

where ρ denotes the radius of the annular groove from the centrally positioned aperture within the annular groove.

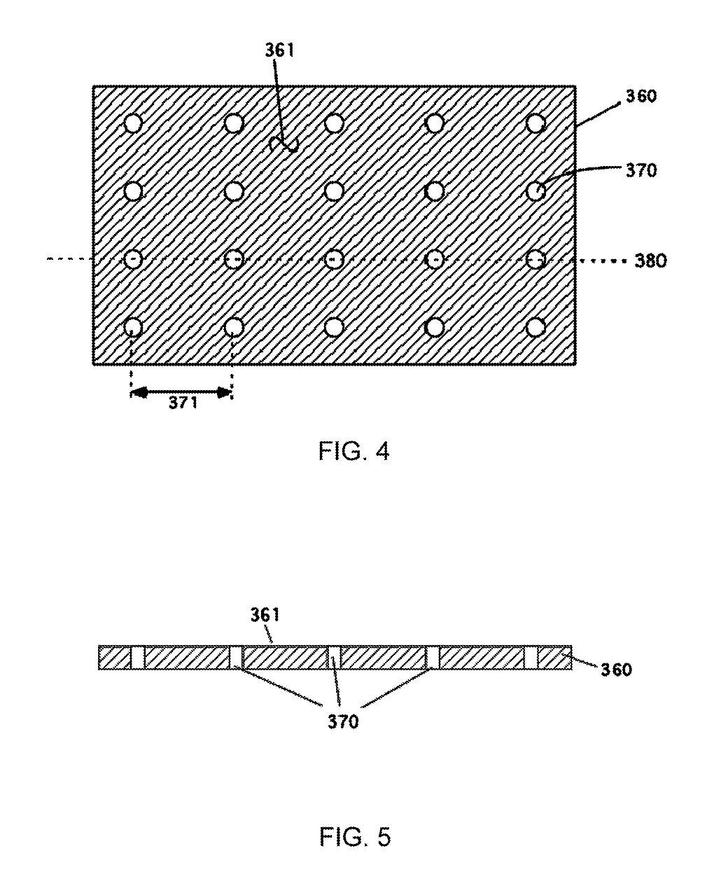

FIG. 5 shows a cross section view of the metal film 360 of FIG. 4 at line 380. The nanoscale features 370 can be filled with any suitable solid, liquid or gas, or vacuum (e.g. a vacuum in holes or voids). Typically, the boundary of the nanoparticle or via or void and its host material is delineated by a change in conductivity of at least one order of magnitude.

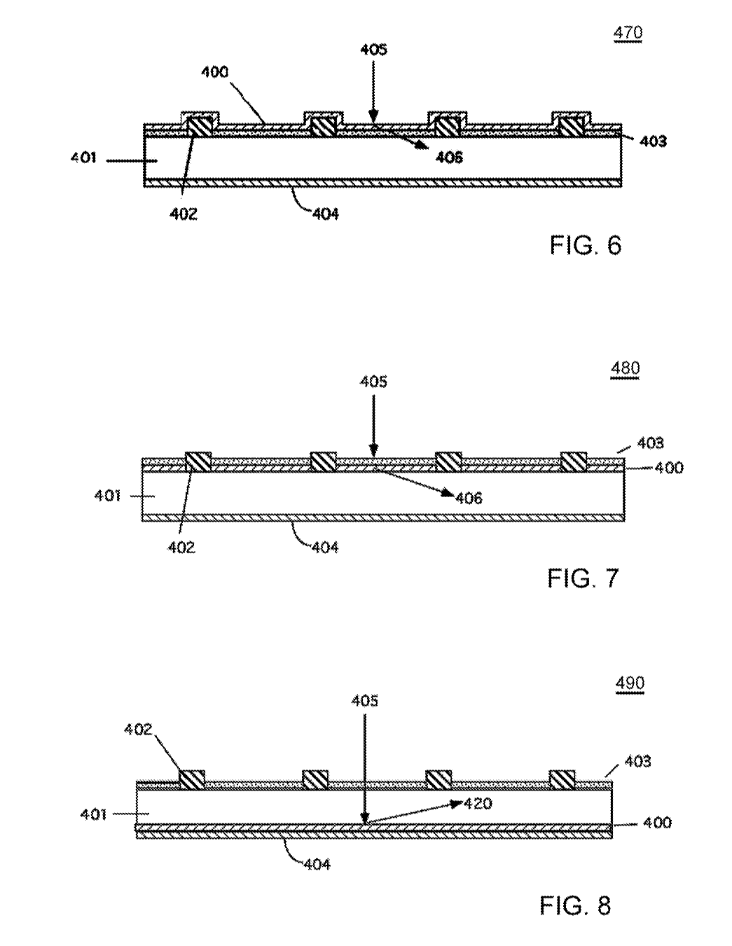

FIG. 6 to FIG. 8 show in more detail examples of how a plasmonic layer 400 can be situated in an integrated solar cell structure. In FIG. 6, plasmonic layer 400 is disposed on a surface of an integrated structure, overlying a collection grid and anti-reflective layer or coating. In FIG. 7, plasmonic layer 400 is disposed between an anti-reflective layer or coating, and in FIG. 8, plasmonic layer 400 is disposed between a solar cell layer and a back contact.

In FIG. 6 to FIG. 8, for simplicity, a light guiding plasmonic layer is used. Light guiding layers, nanoparticle arrays can be employed to reduce the effects of angle of incidence by coupling light into the solar cell (e.g. as light guiding layers). Such nanoparticle layers can change the propagation direction of light within an absorber. The nanoarray can thus couple light from a wide range of angles to photons propagating within the volume of an absorber, such as a solar cell. In this way, the sensitivity to angle of incidence can be reduced.

However, a plasmonic layer 400 can be any type of plasmonic layer, such as an inventive surface plasmon energy conversion device layer. Also as described in more detail hereinbelow, a surface plasmon energy conversion device layer can be combined or stacked with plasmonic light guiding layers and/or plasmonic light concentrating layers where the inventive layers absorb an electromagnetic radiation of a first wavelength and emit a second electromagnetic radiation having a second wavelength. Therefore in some embodiments, plasmonic layer 400 can be taken to include a stack of plasmonic layers including at least one surface plasmon energy conversion plasmonic layer according to the invention. Also, note that in addition to being stacked with plasmonic layers that can change a direction of received electromagnetic radiation, wavelength converting layers (e.g. surface plasmon energy conversion plasmonic layers according to the invention) can also be configured to provide other simultaneous operations such as changing propagation direction and/or to enhance field strength.

FIG. 6 shows an illustration of an integrated solar cell 470 having a plasmonic layer 400, here for example a plasmonic light guiding layer, overlaying a solar cell structure. The solar cell structure includes an absorbing material 401 having a front collection grid 402, anti-reflection (AR) coating 403, and a back contact 404. The absorbing material can be, for example, any suitable thin-film semiconductor such as amorphous silicon, cadmium telluride, or copper indium gallium diselenide. Alternatively, the absorbing material can be any suitable crystalline silicon, amorphous silicon or micro-crystalline silicon. Plasmonic layer 400, including nanoparticles or a nanoparticle layer, formed adjacent to the AR coating 403, provides the desired plasmonic light guiding action. Light rays 405 are modified by plasmonic layer 400 and propagate as rays 406 as they exit the layer 400. Rays 406 can differ from rays 405 by propagation direction. By modifying the rays 405 so that they can be more efficiently absorbed in the solar material 401, an improvement in solar cell conversion efficiency is obtained.

FIG. 7 shows an illustration of an exemplary plasmonic structure which the plasmonic nanoparticle layer 400 is placed below the AR coating 403 and includes cylinders of silver. Such cylinders can have a diameter in the range of 50 to 180 nm, a thickness in the range of 30 to 50 nm and a pitch (distance between cylinder centers) of between 2 and 6 times the cylinder diameter, with the cylinders arranged on a square lattice. The nanoparticle layer parameters can be chosen, for example, so as to minimize the absorption of light at shorter wavelengths (<600 nm), and to maximize the scattering of light at longer wavelengths (>600 nm) to enhance absorption of longer wavelengths. Preferably the direction of light 406 scattered into the absorbing layer 401 is such that the light is totally internally reflected within the absorbing layer 401.

FIG. 8 shows an illustration of another exemplary plasmonic structure in which the plasmonic nanoparticle layer 400 is placed between the absorbing layer 401 and the back contact layer 404. Layer 400 includes cylinders of silver metal. The cylinders can have a diameter of between 50 and 180 nm, a thickness of between 30 and 50 nm and a pitch of between 2 and 6 times the cylinder diameter, with the cylinders arranged on a square lattice. When the plasmonic nanoparticle layer is to be located behind the absorbing layer, the nanoparticle layer parameters can be chosen to maximize the scattering of light at the wavelengths that are weakly absorbed by the absorbing layer 401, generally the longer wavelength portion of the spectrum. Accordingly, the physical lengths of the cylinders or other shaped nanoparticles are typically made longer than, for example, cylinders that might be used in the structures of FIG. 6 or FIG. 7.

A plasmonic nanoparticle layer 400 (as well as any of the inventive plasmonic nanoparticle layers described herein) can be formed integrally with a solar cell or photovoltaic layer as part of a manufacturing process. Alternatively, a plasmonic nanoparticle layer 400 (as well as any of the inventive plasmonic nanoparticle layers described herein) can be added, such as for example, between a glass cover and solar cell during a solar cell module or solar panel manufacturing process. Suitable methods for forming these layers include electron beam lithography followed by metal deposition, spin-on processes in which the nanoparticles are suspended in a colloidal or other solution, or by nano-imprinting. Any other suitable integrated manufacturing process as is known in the art can also be used to form plasmonic nanoparticle layers and/or integrated solar cell structures including plasmonic layers.

### Stacking Layers:

Any number of plasmonic nanoparticle layers and or solar cell or photovoltaic layers can be combined into, for example, an integrated solar cell structure. Such plasmonic layers can be single function layers, such as a plasmonic light guiding layer, or surface plasmon energy conversion device layer, such as for example surface plasmon energy conversion layer 200 (FIG. 2A, FIG. 2B), and/or surface plasmon energy conversion layer 310 and/or surface plasmon energy conversion layer 320 (FIG. 3).

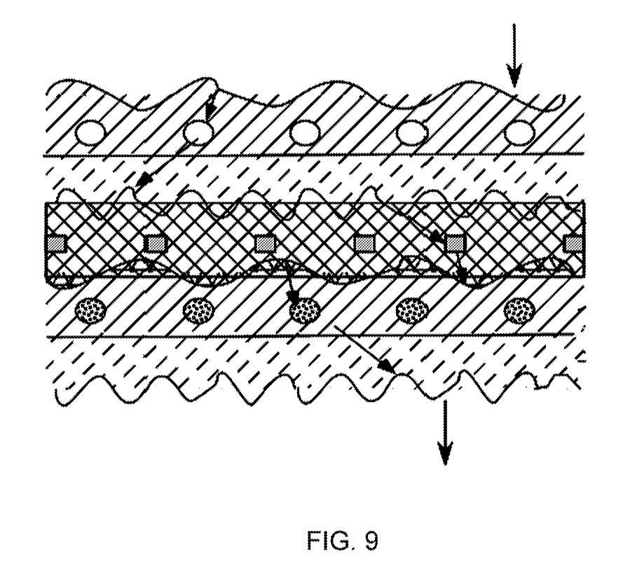

FIG. 9 shows a symbolic representation of one exemplary embodiment of such a stacked structure. Each layer can be unique, or layers can be repeated. Layers can be formed from oxide or nitride dielectrics such as silicon dioxide, titanium dioxide, zinc oxide, tin oxide, indium oxide, silicon nitride, aluminum nitride, boron nitride, titanium nitride or from any other suitable materials.

Stacking layers, such as are shown in FIG. 9, can be used to accomplish a sequence of wavelength shifts of a single input wavelength, or can be designed to shift the wavelength of a wide portion of the spectrum. For example, a “progressive stacking” of nanoparticle layers, each which performs a small shift in wavelength, can be used for example, to shift visible and ultraviolet photons to infrared, where infrared wavelengths are more efficiently absorbed by the solar cell or photovoltaic materials. Stacking of layers also permits modification of the propagation direction of a wide spectrum. The combination of wavelength shifting and concentration by propagation direction control can thus be used to make more efficient infrared concentrator optics.

### Energy Converting Plasmonic Layers:

It is believed that a new type of energy conversion device as is described in more detail hereinbelow is also made possible by plasmonic nanoparticle layers similar to the surface plasmon energy conversion layers described hereinabove. It is believed that such energy conversion devices can convert light energy directly to electrical energy without the use of a conventional solar cell or photovoltaic layer. As described hereinbelow in more detail, it is believed that electrical currents can be caused to flow directly by traveling surface plasmon waves forcing electron flow in a net direction. It is also believed that such traveling waves can be induced by field anisotropy caused by nanoparticles having an asymmetric shape. As used herein, an asymmetric shape lacks symmetry along at least one axis. For example, in Cartesian coordinates, a triangle can be symmetric along, for example a y axis, but not at the same time symmetric along the x axis. Therefore, as used herein, a triangular shape is an asymmetric shape. It is contemplated that such energy conversion devices can be used as the only energy conversion layer or such energy conversion device layers can be present in multilayer structures as additional layers along other energy conversion plasmonic layers, other conventional photovoltaic layers, or any combination thereof.

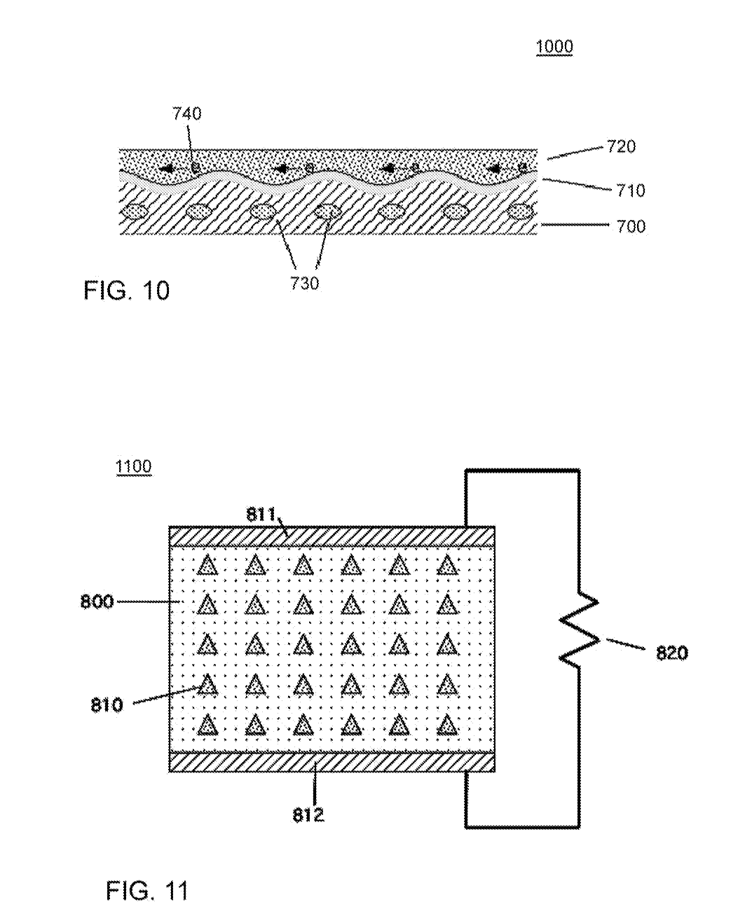

FIG. 10 shows a symbolic diagram which illustrates the principle of operation of the new energy converting plasmonic device. In the exemplary embodiment of FIG. 10, a transparent conductive layer 720 such as for example, indium tin oxide (ITO) is in contact with a plasmonic nanoparticle layer 700. Incident electromagnetic radiation, such as light incident through conductor 720, excites a surface plasmon resonance on nanoparticle layer 700. The plasmon resonant frequencies are influenced by a plurality of aligned nanoparticles 730 dispersed with nanoparticle layer 700 where nanoparticles 730 are, for example, disposed in a lattice pattern. The shapes of the nanoparticles 730 can be designed to induce a traveling electromagnetic wave caused by the plasmons. The traveling electromagnetic wave will transfer momentum to electrons in 720 in a manner similar to the momentum transfer to charged particles in a traveling wave particle accelerator used in high energy physics research facilities, and the electrons in layer 720 will be induced to flow in the direction of the traveling electromagnetic wave constituting a current. Alternatively, birefringent material (or other material such as a piezoelectric material) 710 can be added at the interface to create a transverse electric field component that extends into material 720. As a consequence of the transverse field, momentum is transferred to electrons in 720 thus generating an electrical current. It is the presence of nanoparticles having asymmetric shape that provides the field anisotropy needed for current to flow in a preferred direction.

FIG. 11 shows an illustration of one exemplary embodiment of an energy converting plasmonic device 1100 formed in accordance with the methods and materials of forming plasmonic layers as described hereinabove. In the exemplary embodiment shown in FIG. 11, each nanoparticle 810 of an array of metallic nanoparticles 810 has a triangular cross section and nanoparticles 810 lie substantially in a plane defined by dielectric media layer 800. The electric field will be higher at the narrow end of each nanoparticle 810 because of both the shape (e.g. triangular) of nanoparticles 810 and/or the orientation of each nanoparticle 810 with respect to the other nanoparticles 810. Contact 811 and contact 812 are provided so that current induced by the triangular shapes (in accordance with the field effects shown in FIG. 10) can be collected and delivered to an external circuit 820. The shape and/or orientation of nanoparticles 810 causes a flow of electrical current through electrical load impedance 820 via electrical contact 811 and electrical contact 812.

A rectenna is defined herein to mean a rectifying antenna useful for converting a received electromagnetic radiation into an electrical current. It is also believed that rectennas can be created using these techniques by, for example, by assembling structures such as those shown in FIG. 11 into large interconnected arrays. Alternatively, the energy in the surface plasmons can be coupled into nanowires placed in proximity to the nanoparticle lattice of an energy converting plasmonic device 1100. It is also believed that such energy converting plasmonic device layers can be useful as photodetector devices.

FIG. 12 shows another embodiment of an energy converting plasmonic device 1200 having a nanowire layer 1201. Nanowire layer 1201 can be made from, for example, an array of parallel conducting channels. Such parallel conducting channels can be made of nanowires aligned so that the electric field from the plasmons points along the direction of the wires. In FIG. 12, an exemplary nanowire layer 1201 is shown disposed between a transparent layer 720 and a plasmonic nanoparticle layer 700. Nanowire layer 1201 can alternatively be disposed adjacent to the opposite side of plasmonic nanoparticle layer 700 (not shown). It is contemplated that if a nanowire layer 1201 is placed within about 50 nanometers of plasmonic nanoparticle layer 700, the evanescent EM field from the plasmons can enter nanowire layer 1201 and/or plasmonic nanoparticle layer 700 so that the electric field from the plasmons points along the direction of the wires and causes an electrical current to flow between electrical terminal 750 and electrical terminal 751.

FIG. 14 shows another embodiment of an energy converting plasmonic device 1400 using either a plane of conductive material 1401 made from any suitable type of electrically conducting element, such as for example, very thin graphene, or the plane of conductive material 1401 can be made of arrays of nanowires separated by non-conducting material, or it is contemplated that there can be a continuous plane of any suitable conductive material 1401, such as any suitable highly transparent and electrically conducting material.

FIG. 13 shows one exemplary embodiment of an energy converting plasmonic device 1300 using a graphene layer 1301. Graphene layer 1301, having a low electrical first resistance) within the plane of the graphene layer 1301 and a higher resistance than the first resistance, and optical transparency, perpendicular to the plane of the graphene layer 1301, can be disposed adjacent to a plasmonic nanoparticle layer 700. It is contemplated that a graphene layer 1301 can confine the electrons that receive the plasmon energy to a 2-dimensional structure.

Reina, et al., “Transferring and Identification of Single- and Few-Layer Graphene on Arbitrary Substrates,” Journal of Physical Chemistry C, 2008, 112 (46), pages 17741-17744, have described one exemplary graphene deposition technique. Using the Reina process, features across large areas (cm²) having single and few-layer graphene flakes obtained by the microcleaving of highly oriented pyrolytic graphite (HOPG) were reliably transferred to dissimilar material. Reina's approach is also believed to be suitable for the fabrication of graphene devices on a substrate material other than SiO₂/Si.

It is also contemplated that a graphene layer 1301 can replace a transparent conductive layer 720 (FIG. 11, FIG. 12), because a relatively thin graphene layer has a high conductivity within the graphene plane and also has a high optical transparency. Note that because of the high optical transparency, it is believed that electrons can be transported parallel to the surface of graphene layer 1301.

### Manufacturing Processes:

Dennis Slafer of the MicroContinuum Incorporated of Cambridge, Mass., has described several manufacturing techniques and methods that are believed to be suitable for the manufacture of surface plasmon wavelength converter devices as described herein. For example, U.S. patent application Ser. No. 12/358,964, ROLL-TO-ROLL PATTERNING OF TRANSPARENT AND METALLIC LAYERS, filed Jan. 23, 2009, describes and teaches one exemplary manufacturing process to create metallic films having a plurality of nanofeatures suitable for use in surface plasmon wavelength converter devices as described herein. Also, U.S. patent application Ser. No. 12/270,650, METHODS AND SYSTEMS FOR FORMING FLEXIBLE MULTILAYER STRUCTURES, filed Nov. 13, 2008, U.S. patent application Ser. No. 11/814,175, Replication Tools and Related Fabrication Methods and Apparatus, filed Aug. 4, 2008, U.S. patent application Ser. No. 12/359,559, VACUUM COATING TECHNIQUES, filed Jan. 26, 2009, and PCT Application No. PCT/US2006/023804, SYSTEMS AND METHODS FOR ROLL-TO-ROLL PATTERNING, filed Jun. 20, 2006 describe and teach related manufacturing methods which are also believed to be useful for manufacturing surface plasmon wavelength converter devices as described herein. Each of the above identified United States and PCT applications is incorporated herein by reference in its entirety for all purposes.

Also, it is noted that a “via” is believed to be one exemplary integrated structure which can be used to make suitable nanofeatures in a metallic film or TCO film layer. Vias can be created in an integrated layer using any suitable lithography or nanoprinting manufacturing process.

### Applications

As described hereinabove, surface plasmon energy conversion devices according to the invention can be used to improve the efficiency and operation of photovoltaic solar cells and panels. Also, as described hereinabove, it is believed that such surface plasmon energy conversion devices can be used to extract useful energy from rectennas and other types of optical antennas. It is also contemplated that surface plasmon energy conversion devices according to the invention can be used to improve transmission and detection of electromagnetic radiation, such as for communications and control applications. It is also contemplated that surface plasmon energy conversion devices according to the invention can be used to improve military signature and/or control devices or objects such as where wavelength conversion can render objects less visible or substantially invisible by wavelength conversion, typically from visible light to ranges of light not visible to the animal or human eye. It is also contemplated that surface plasmon energy conversion devices according to the invention can be used as greenhouse covers to control the wavelength of electromagnetic radiation provided to light and heat living things, such as for example, plants. It is also contemplated that surface plasmon energy conversion devices according to the invention can be used to improve window covers by controlling light and heat, such as for climate control (e.g. to lessen heat loads for air conditioning). It is also contemplated that surface plasmon energy conversion devices according to the invention can be used to improve hydrogen production by enhancing the splitting of water into H and oxygen. It is also contemplated that surface plasmon energy conversion devices according to the invention can be further improved by including superconducting materials, such as for example, metals cooled to below their superconducting transition temperature, which can produce unusual effects upon the disappearance of Plasmon losses (due to the exclusion of the electromagnetic field from the interior of the particles causing the plasmon resonances and subsequent reduction of any losses due to heat production). It is also contemplated that surface plasmon energy conversion devices according to the invention as described hereinabove can be used to improve electromagnetic detectors. It is also contemplated that surface plasmon energy conversion devices according to the invention as described hereinabove can be used to provide novel electromagnetic transmission devices and systems.

Although the theoretical description given herein is thought to be correct, the operation of the devices described and claimed herein does not depend upon the accuracy or validity of the theoretical description. That is, later theoretical developments that may explain the observed results on a basis different from the theory presented herein will not detract from the inventions described herein.

Any patent, patent application, or publication identified in the specification is hereby incorporated by reference herein in its entirety. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

While the present invention has been particularly shown and described with reference to the preferred mode as illustrated in the drawing, it will be understood by one skilled in the art that various changes in detail may be affected therein without departing from the spirit and scope of the invention as defined by the claims.

What is claimed is:

1. A surface plasmon energy converter device, comprising:
a first layer having a first layer dielectric constant, a first layer first surface and a first layer second surface;
a plurality of nanofeatures disposed in or on said first layer; and
a second layer having a second layer dielectric constant and a second layer first surface and a second layer second surface, said second layer second surface disposed adjacent to and optically to said first layer second surface, said second layer dielectric constant differing from said first layer dielectric constant;
wherein said surface plasmon energy converter device is configured to respond to an incident electromagnetic radiation having a first wavelength by radiating away from said surface plasmon wavelength converter device an electromagnetic radiation having a second wavelength different from said first wavelength.

2. The surface plasmon energy converter device of claim 1, wherein said first layer having a first plurality of nanofeatures is configured to absorb said first wavelength.

3. The surface plasmon energy converter device of claim 1, wherein said second layer is configured to radiate an electromagnetic radiation at said second wavelength.

4. The surface plasmon energy converter device of claim 1, further comprising an interfacial layer disposed between said first layer second surface and said second layer second surface.

5. The surface plasmon energy converter device of claim 4, wherein said interfacial layer has a thickness substantially equal to or less than 15 nm.

6. The surface plasmon energy converter device of claim 1, wherein said first layer comprises a selected one of oxide and nitride dielectric.

7. The surface plasmon energy converter device of claim 6, wherein said dielectric is selected from the group consisting of oxide, nitride dielectric, silicon dioxide, titanium dioxide, zinc oxide, tin oxide, indium oxide, silicon nitride, aluminum nitride, boron nitride, and titanium nitride.

8. The surface plasmon energy converter device of claim 1, wherein said nanofeatures comprise a selected one of silver, gold, copper, aluminum, metal alloy, and mercury.

9. The surface plasmon energy converter device of claim 1, wherein said nanofeatures are sized in a range of approximately 50 nm to 200 nm.

10. An integrated solar cell, comprising:
a surface plasmon energy converter device according to claim 1 having at least one solar cell layer optically coupled thereto, and
a first positive electrical terminal and a second negative terminal, said first positive electrical terminal and said second negative terminal configured to provide an electrical current and an electrical voltage as output signals.

11. The integrated solar cell of claim 9, further comprising at least one additional surface plasmon energy converter device, said additional second surface plasmon wavelength converter device optically coupled to said solar cell.

12. A surface plasmon energy converter device, comprising:
a first layer having a first plurality of nanofeatures disposed on a first layer first surface, and a first layer second surface; and
a second layer having a second plurality of nanofeatures disposed on a second layer first surface, and a second layer second surface disposed adjacent to and optically coupled to said first layer second surface, and
wherein said surface plasmon energy converter device is configured to respond to an incident electromagnetic radiation having a first wavelength by radiating away from said surface plasmon wavelength converter device an electromagnetic radiation having a second wavelength different from said first wavelength.

13. The surface plasmon energy converter device of claim 12, wherein said first layer having a first plurality of nanofeatures is configured to absorb said electromagnetic radiation at said first wavelength.

14. The surface plasmon energy converter device of claim 12, wherein said second layer having a second plurality of nanofeatures is configured to radiate said electromagnetic radiation at said second wavelength.

15. The surface plasmon energy converter device of claim 12, wherein said first plurality of nanofeatures comprises a metal.

16. The surface plasmon energy converter device of claim 15, wherein said metal comprises silver.

17. The surface plasmon energy converter device of claim 12, wherein said first plurality of nanofeatures comprises cylinders having a diameter of approximately 50 to 180 nm, a thickness of approximately 30 to 50 nm and a pitch of about two to six times the cylinder diameter.

18. The surface plasmon energy converter device of claim 12, wherein said first plurality of nanofeatures is arranged in a square lattice.

19. The surface plasmon energy converter device of claim 12, wherein said first plurality of nanofeatures comprises shapes selected from the group consisting of a triangle and a cylinder.

20. The surface plasmon energy converter device of claim 12, wherein said first layer comprises a dielectric material.

21. The surface plasmon energy converter device of claim 12, wherein said first layer comprises a selected one of oxide and nitride dielectric.

22. The surface plasmon energy converter device of claim 20, wherein said dielectric is selected from the group consisting of oxide, nitride dielectric, silicon dioxide, titanium dioxide, zinc oxide, tin oxide, indium oxide, silicon nitride, aluminum nitride, boron nitride, and titanium nitride.

23. An integrated solar cell, comprising:
a surface plasmon energy converter device according to claim 12 having at least one solar cell layer optically coupled thereto, and
a first positive electrical terminal and a second negative terminal, said first positive electrical terminal and said second negative terminal configured to provide an electrical current and an electrical voltage as output signals.

24. The integrated solar cell of claim 23, further comprising at least one additional surface plasmon energy converter device, said additional second surface plasmon wavelength converter device optically coupled to said solar cell.

25. A surface plasmon energy converter device for generating electricity, comprising:
a first layer having a first layer dielectric constant, a first layer first surface and a first layer second surface;
a second layer having a second layer dielectric constant and a plurality of nanofeatures having an asymmetric shape disposed on or in said second layer, a second layer first surface and a second layer second surface, said second layer second surface disposed adjacent to and optically to said first layer second surface; and
a first electrical terminal and a second electrical terminal, and
wherein said surface plasmon energy converter device is configured to respond to an incident electromagnetic radiation having a first wavelength by causing an electrical current to flow between said first electrical terminal and said second electrical terminal.

26. The surface plasmon energy converter device of claim 25, wherein said asymmetric shape comprises a triangular shape.

27. The surface plasmon energy converter device of claim 25, wherein said first layer comprises a transparent layer.

28. The surface plasmon energy converter device of claim 27, wherein said transparent layer comprises indium tin oxide.

29. The surface plasmon energy converter device of claim 25, wherein said nanofeatures are disposed in a lattice pattern.

30. The surface plasmon energy converter device of claim 25, wherein said incident electromagnetic radiation comprises photons of light.

31. The surface plasmon energy converter device of claim 25, wherein said surface plasmon energy converter device is configured as a rectenna, a rectifying antenna which converts a received electromagnetic radiation into an electrical current.

32. The surface plasmon energy converter device of claim 31, wherein said incident electromagnetic radiation comprises radio waves.

33. The surface plasmon energy converter device of claim 25, further comprising an additional layer disposed between said first layer and said second layer, said additional layer comprising nanowires.

34. The surface plasmon energy converter device of claim 25, further comprising an additional layer disposed between said first layer and said second layer, said additional layer comprising graphene.

35. The surface plasmon energy converter device of claim 25, wherein said first layer comprises a selected one of graphene and nanowires

36. The surface plasmon energy converter device of claim 25, wherein said first layer comprises a material having a first resistance in a plane of said first layer and a second resistance perpendicular to said plane of said first layer and said first resistance is less than said second resistance.
